(19) United States
(12) Patent Application Publication
(10) Pub. No.: US 2005/0227452 A1
(43) Pub. Date: Oct. 13, 2005

(54) Method for producing semiconductor device

(75) Inventors: Takuo Ohashi, Tokyo (JP); Takeshi Suwa, Tokyo (JP); Taishi Kubota, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC

(21) Appl. No.: 11/103,613

(22) Filed: Apr. 12, 2005

(30) Foreign Application Priority Data
Apr. 13, 2004 (JP) 2004-117798

(51) Int. Cl. H01L 21/762

(52) U.S. Cl. 438/425

(57) ABSTRACT

A method for producing a semiconductor device includes the steps of forming a trench for device isolation on a silicon substrate; and annealing the silicon substrate in an atmosphere containing a noble gas at any step after the growth of a buried oxide film until the growth of a gate polysilicon.

This application claims priority to prior Japanese patent application JP 2004-117798, the disclosure of which is incorporated herein by reference.

### BACKGROUND OF THE INVENTION

The present invention relates to methods for producing semiconductor devices, and particularly relates to a method for producing a semiconductor device without deterioration of device characteristics by improving the reliability of a gate oxide film at the boundary between a trench-isolation region and an active region.

Larger-scale, higher-speed semiconductor devices have increasingly been demanded in recent years. In order to meet the demand, STI (shallow trench isolation) has been used as a method for isolating devices. In STI, an insulating film is buried in a trench to achieve isolation. This method therefore causes no bird's beak in contrast to LOCOS (local oxidation of silicon), and is suitable for achieving high integration.

In STI, however, square STI corners are formed at the boundary between an active region, namely a main silicon surface, and an isolation region, namely a trench. As a result, a gate oxide film has thin parts on the corners, and thus an electric field concentrates on the corners. These corners therefore undesirably deteriorate the reliability of the gate oxide film and the performance of the transistor.

In the related art, the inner wall of an STI trench is oxidized and nitrided to form an inner-wall oxynitride film which is left so as not to expose the STI corners. This oxynitride film inhibits the formation of thin parts of the gate oxide film and the concentration of an electric field to improve the reliability of the gate oxide film.

For example, the above-mentioned related art is disclosed in Japanese Unexamined Patent Application Publications (JP-A) Nos. 2001-135720, 64-33935, 4-103173 and 10-41241.

In the above-related art, however, nitrogen contained in the oxynitride film acts as positive charges to adversely affect the silicon interface. In addition, even though the inner wall of the trench is oxynitrided, the formation of the gate oxide film is suppressed, and thus the film has thin parts. The related art therefore undesirably deteriorates the reliability of the gate oxide film and the performance of the transistor because the gate oxide film has thin parts and an electric field concentrates.

### SUMMARY OF THE INVENTION

It is therefore an object of the present invention is to provide a method for producing a highly reliable semiconductor device which is capable of improving reliability of a gate oxide film without local variations in thickness of the gate oxide film.

The present invention provides a method for producing a semiconductor device. This method includes the steps of forming a trench for device isolation on a silicon substrate; and annealing the silicon substrate in an atmosphere containing a noble gas at any step after the growth of a buried oxide film until the growth of a gate polysilicon to round STI corners.

In the method for producing a semiconductor device according to the present invention, the noble gas is preferably argon, neon, or helium.

In the method for producing a semiconductor device according to the present invention, the annealing is preferably performed at 1,000° C. to 1,200° C. for ten minutes to five hours.

In the method for producing a semiconductor device according to the present invention, the silicon substrate is preferably annealed without being exposed while the silicon substrate is covered with an insulating film.

In the method for producing a semiconductor device according to the present invention, the annealing is preferably performed immediately before channel injection.

In the method for producing a semiconductor device according to the present invention, the annealing is preferably performed immediately before the growth of a gate polysilicon.

In the method for producing a semiconductor device according to the present invention, the annealing is preferably performed immediately before CMP.

In the method for producing a semiconductor device according to the present invention, the annealing is preferably performed immediately before the removal of a pad oxide film.

In the method for producing a semiconductor device according to the present invention, the step of annealing at high temperature in a noble gas atmosphere may be added in the process after the growth of a buried oxide film until the growth of a gate polysilicon to round STI corners at the boundary between isolation and active regions. Further, the step of annealing in a noble gas atmosphere does not involve the effect of nitrogen on the oxide films and the silicon interface, and therefore provides stable fixed charge and interface level. Thus this method can produce a highly reliable semiconductor device by rounding the corners, eliminating the effect of nitrogen on the silicon interface, and forming a highly reliable gate oxide film with no local variations in thickness.

### BRIEF DESCRIPTION OF THE DRAWINGS

FIG. 1 is a flow chart showing a process according to a first embodiment;

FIGS. 2A to 2E are sectional views of a semiconductor device according to the first embodiment;

FIGS. 3A to 3D show the shapes of corners;

FIG. 4 is a graph showing the correlation between annealing steps and the radius of curvature of the corners;

FIG. 5 is a graph showing the correlation between annealing times and the radius of curvature of the corners;

FIG. 6 is a graph showing a CV curve;

FIG. 7 is a graph showing the correlation between annealing conditions and the capacitance in an inversion mode;

FIG. 8 is a graph showing the correlation between annealing conditions and Qbd;

FIG. 9 a graph showing Vg-Id characteristics; and

FIG. 10 is a graph showing the correlation between annealing conditions and threshold values.

### DESCRIPTION OF THE PREFERRED EMBODIMENTS

Methods for producing a semiconductor device according to the present invention will now be described with reference to the drawings.

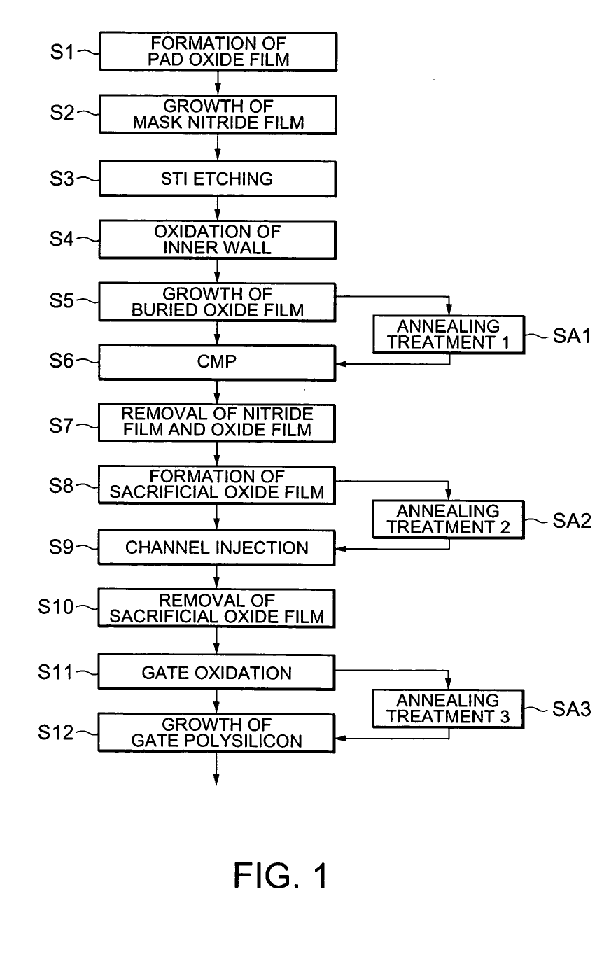

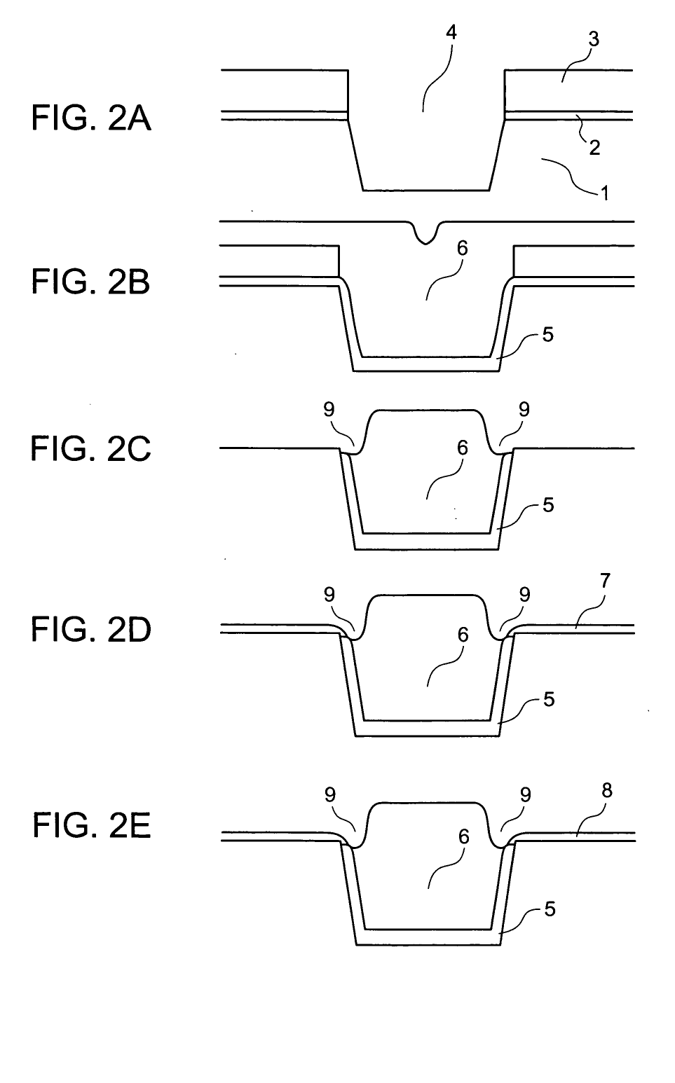

First, a pad oxide film 2 with a thickness of 9 nm and a nitride film 3 with a thickness of 140 nm are formed on the main surface of a silicon substrate 1, as shown in steps S1 and S2 of FIG. 1 and FIG. 2A. The nitride film 3 and the pad oxide film 2 are then etched by photolithography, and the silicon substrate 1 is etched to form a trench 4, as shown in a step S3 of FIG. 1 and FIG. 2A. The inner wall of the trench 4 is oxidized to form an inner-wall oxide film 5 with a thickness of 20 nm. The trench 4 is then fully filled with a buried oxide film 6, as shown in steps S4 and S5 of FIG. 1 and FIG. 2B.

The buried oxide film 6 is polished by chemical mechanical polishing (CMP) until the nitride film 3 is exposed, as shown in a step S6 of FIG. 1 and thus a flat surface is formed. The nitride film 3 and the pad oxide film 2 are then removed to expose an active region, as shown in a step S7 of FIG. 1 and FIG. 2C. Overetching occurs in the removal of the nitride film 3 and the pad oxide film 2. As a result, the top of the inner-wall oxide film 5 is etched to expose parts of the inner wall of the trench 4 on the silicon substrate 1. STI corners refer to the boundaries between the inner wall of the trench 4 and the main surface of the silicon substrate 1. The STI corners are square at this time. The silicon substrate 1 is exposed at the STI corners, and grooves referred to as divots 9 shown in FIG. 2C are formed between the isolation and active regions.

A sacrificial oxide film 7 with a thickness of 10 nm is formed, as shown in a step S8 of FIG. 1 and FIG. 2D. This oxide film 7 is thinner at the square STI corners than on the main surface. The sacrificial oxide film 7 is removed after ion injection for adjusting the threshold value of the transistor, as shown in steps S9 and S10 of FIG. 1. Overetching occurs in the removal of the sacrificial oxide film 7. As a result, the silicon substrate 1 is exposed again at the STI corners, which are still square.

A gate oxide film 8 is formed, as shown in a step S11 of FIG. 1 and FIG. 2E. The gate oxide film 8 has thin parts on the square STI corners, and thus an electric field concentrates on the corners. A gate polysilicon film is allowed to grow on the gate oxide film 8, and the rest of the transistor production process is performed, as shown in a step S12 of FIG. 1.

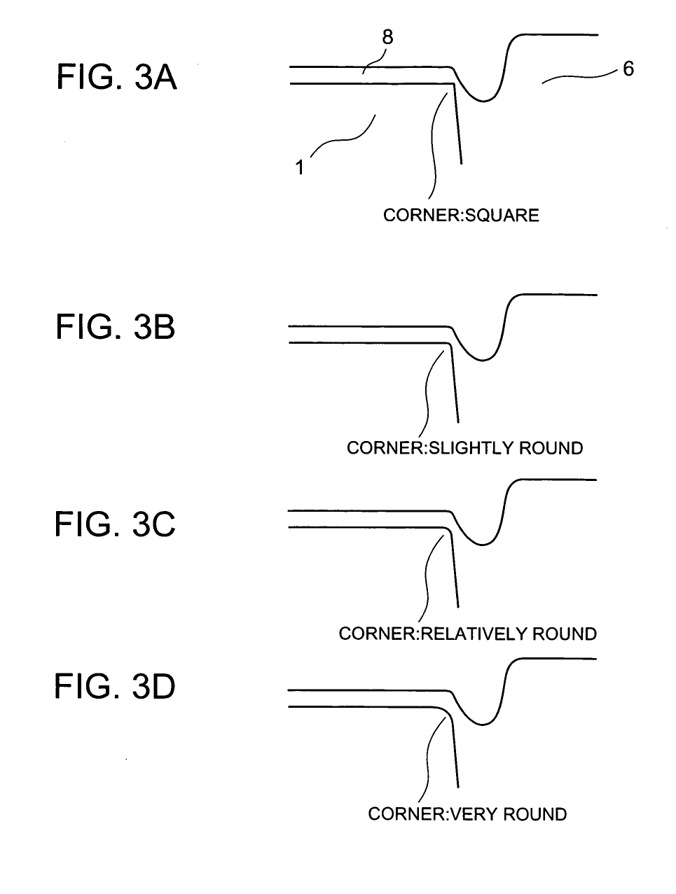

In the above main steps S1 through S12 of the normal transistor production process by STI, the present inventor has conceived the approach of modifying the shape of the STI corners by annealing in order to improve the reliability of the gate oxide film 8. Annealing treatments 1, 2, and 3 are added to the process, as annealing steps SA1 to SA3, as shown in the right of FIG. 1. Checks have been made on the rounding of the STI corners between the isolation and active regions and the dependence on the annealing atmosphere. The resultant check data is shown in FIGS. 3A to 10.

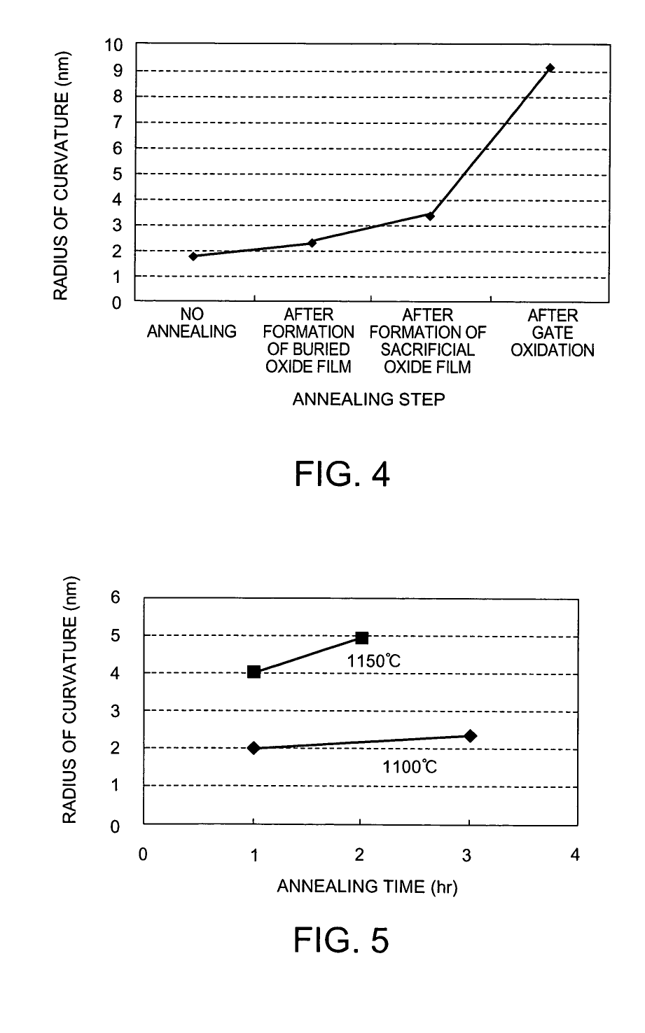

FIGS. 3A to 4 show the comparison results of the cases of adding no annealing step, adding the annealing step SA1 after the growth of the buried oxide film 6, adding the annealing step SA2 after the formation of the sacrificial oxide film 7, and adding the annealing step SA3 after the formation of the gate oxide film 8. The annealing steps SA1 to SA3 were performed in a nitrogen atmosphere at 1,000° C. for one hour. According to the results, the annealing step SA1 after the growth of the buried oxide film 6 achieved an increase of about 0.5 nm in radius of curvature, namely a radius of curvature exceeding 2 nm, in comparison with the radius of curvature with no annealing step. The annealing step SA2 after the formation of the sacrificial oxide film 7 achieved an increase of about 1.5 nm in radius of curvature, namely a radius of curvature of 3.5 nm. The annealing step SA3 after the formation of the gate oxide film 8 achieved an increase of about 7 nm in radius of curvature, namely a radius of curvature of 9 nm.

FIGS. 3A to 3D show the observation results of these shapes. FIG. 3A shows the shape with no annealing step. FIG. 3B shows the shape with the annealing step SA1 after the growth of the buried oxide film 6. FIG. 3C shows the shape with the annealing step SA2 after the formation of the sacrificial oxide film 7. FIG. 3D shows the shape with the annealing step SA3 after the formation of the gate oxide film 8. The shapes of the STI corners are better, namely rounder, in the order of FIGS. 3A to 3D. Accordingly, the best annealing step for rounding the corners is the annealing step SA3 after the formation of the gate oxide film 8. The second is the annealing step SA2 after the formation of the sacrificial oxide film 7, and the third is the annealing step SA1 after the growth of the buried oxide film 6.

The shapes shown in FIGS. 3A to 3D were observed after the transistors were formed. According to the check results at the individual steps, the STI corners are rounded by annealing after the formation of any oxide film. After the annealing, the oxide film is removed to expose the silicon substrate 1, and another oxide film is formed on the substrate 1. The rounded corners then become square again by the oxidation. If the corners are annealed after the formation of the gate oxide film 8, the film 8 is left to the end without being removed so that the corners are kept rounded. If the corners are annealed after the formation of the sacrificial oxide film 7, the rounded STI corners become less round by the gate oxidation after the removal of the sacrificial oxide film 7. If the corners are annealed after the formation of the buried oxide film 6, the rounded STI corners become still less round by two oxidation steps for forming the sacrificial oxide film 7 and the gate oxide film 8. The gate oxide film 8 formed on the rounded STI corners has higher reliability than with no annealing step.

FIG. 5 shows the results of the dependence on annealing temperatures and times, where the annealing step SA2 was performed after the formation of the sacrificial oxide film 7 in a nitrogen atmosphere. These results show that the annealing at 1,100° C. achieved a small increase in the radius of curvature of the corners while the annealing at 1,150° C. achieved a larger increase in the radius of curvature and had greater dependence on time. Thus the annealing is preferably performed at a higher temperature for a longer time.

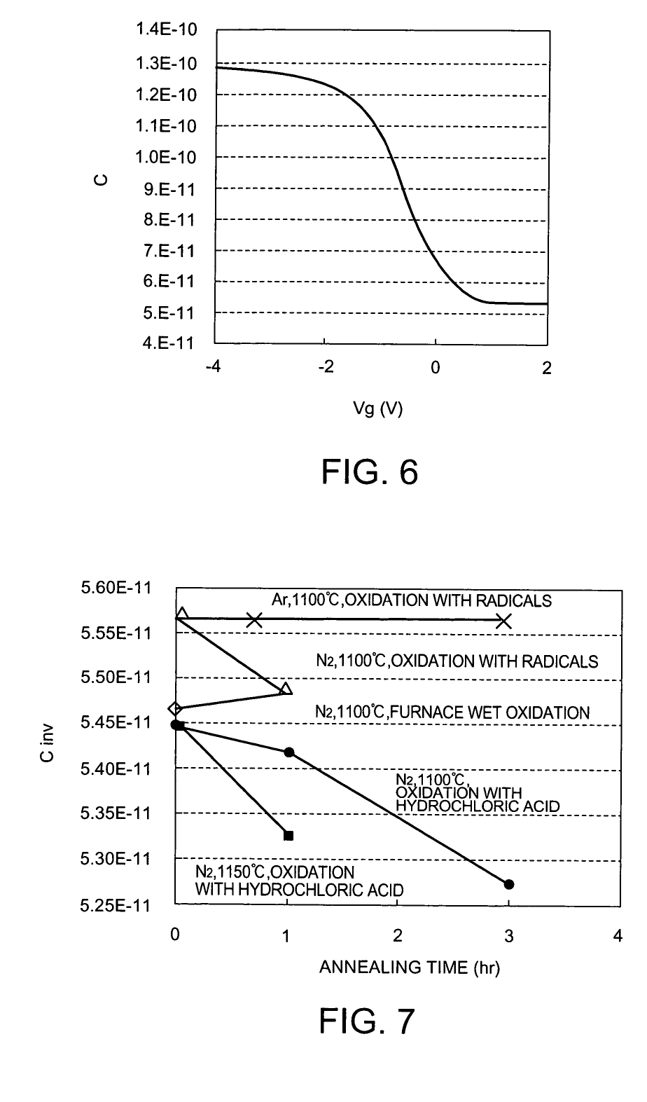

FIG. 7 shows the dependence on the annealing conditions and the gate oxidation conditions, where the annealing was performed after the formation of the sacrificial oxide film 7. The capacitance Cinv between the gate and the substrate 1 in an inversion mode was measured and compared by the CV method. In this method, the quality of the gate oxide film 8 and its interface was evaluated according to the capacitance in accumulation, depletion, and inversion modes by applying voltage across the gate and the substrate 1, as shown in FIG. 6.

Referring to FIG. 7, the capacitance in the inversion mode showed no change after annealing in a nitrogen atmosphere at 1,100° C. for one hour and furnace wet oxidation, and decreased after annealing in a nitrogen atmosphere and oxidation with radicals or hydrochloric acid. The decreases in capacitance were larger at higher temperatures for longer times. On the other hand, the capacitance showed no decrease after annealing in an argon atmosphere at 1,100° C. for either one or three hours and gate oxidation with radicals.

These results are probably due to intrusion or invasion of nitrogen into the oxide films in the active region and on the inner wall of the trench 4 during the annealing in a nitrogen atmosphere at high temperature. Even if the sacrificial oxide film 7 in the active region is removed and the gate oxide film 8 is newly formed, the capacitance in the inversion mode decreases by the effect of nitrogen remaining at the silicon interface in the active region and in the inner-wall oxide film 5 at the boundary between the isolation and active regions. On the other hand, such reaction does not occur for the annealing in the noble gas, namely argon gas, and the capacitance in the inversion mode is not affected and therefore shows no decrease.

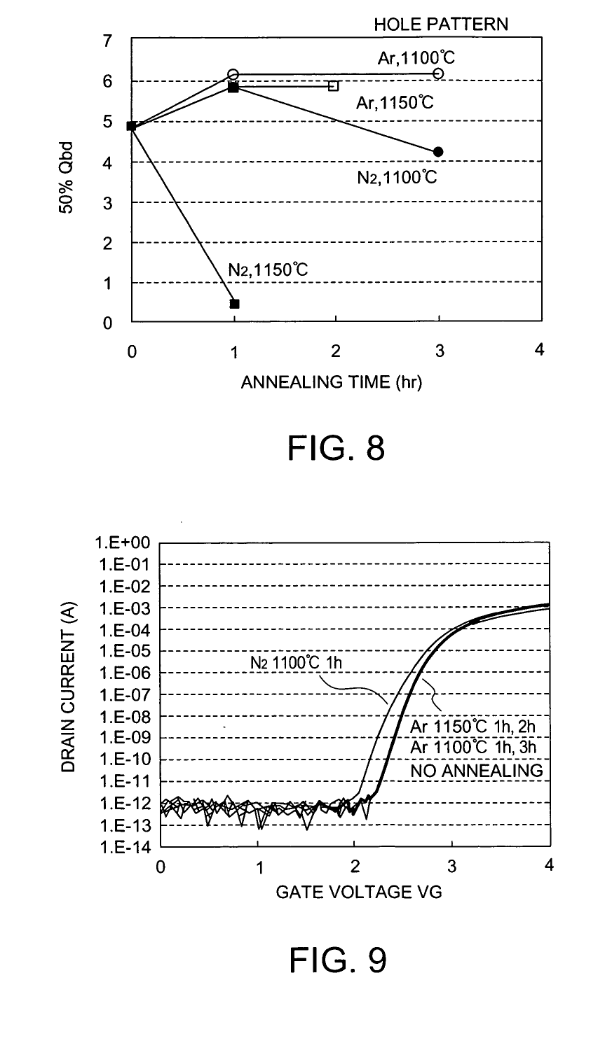

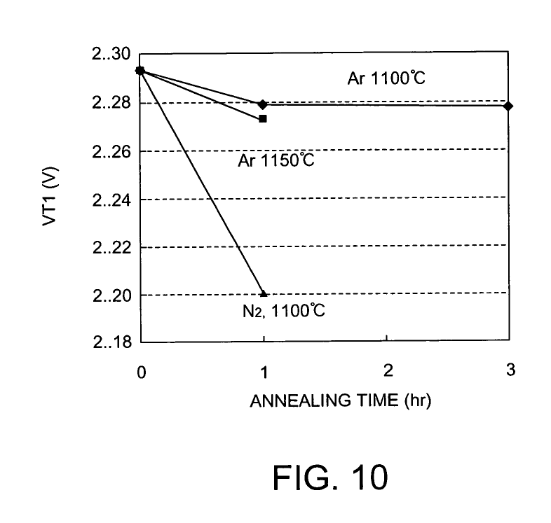

Further, the annealing after the formation of the sacrificial oxide film 7 was performed under varying conditions to confirm the above results. FIG. 8 shows the Qbd (charge to breakdown) of the gate oxide film 8. FIG. 9 shows the Vg-Id characteristics of the transistor. FIG. 10 shows the threshold value of the transistor. In FIG. 8, the 50% Qbd values increased after annealing in an argon atmosphere either at 1,100° C. or at 1,150° C. and after annealing in a nitrogen atmosphere at 1,100° C. for one hour, but decreased after annealing in a nitrogen atmosphere at 1,100° C. for two hours and at 1,1500° C. for one hour. The annealing in a nitrogen atmosphere at 1,100° C. for one hour enabled the formation of an oxide film with a uniform thickness by the effect of rounding the corners to increase the Qbd while the annealing in a nitrogen atmosphere for two hours or at 1,150° C. decreased the Qbd by the adverse effect of nitrogen.

According to the Vg-Id characteristics of the transistor in FIG. 9, a kink occurred and off-leakage current flowed after the annealing in a nitrogen atmosphere at 1,100° C. for one hour. On the other hand, the results after the annealing in an argon atmosphere either at 1,100° C. or at 1,150° C. were similar to those with no annealing, and no kink occurred. FIG. 10 shows the threshold values measured at a drain current of 10⁻⁸ A. In FIG. 10, the annealing in a nitrogen atmosphere resulted in a largely dropped threshold value.

The above data may be summarized as follows. Annealing can round the corners either in a nitrogen or argon atmosphere. An annealing step may be added in the process after the growth of a buried oxide film until the growth of a gate polysilicon. A silicon substrate may be subjected to the annealing step without being exposed while the substrate is covered with an insulating film such as an oxide film and a nitride film. This annealing step is preferably performed immediately before channel injection, the growth of a gate polysilicon, the removal of a pad oxide film, or CMP.

In addition, annealing in a nitrogen atmosphere at high temperature for a long time deteriorates an oxide film by the adverse effect of nitrogen while annealing in an argon atmosphere at high temperature for a long time causes no deterioration. An argon atmosphere therefore allows annealing at a higher temperature for a longer time in order to round the STI corners sufficiently. Similarly, neon and helium are effective since they are noble gases of Group 0 of the periodic table and are chemically inert.

Further, the annealing temperature preferably ranges from 1,000° C. to 1,200° C., more preferably from 1,100° C. to 1,150° C., and the annealing time preferably ranges from ten minutes to five hours.

In the method for producing a semiconductor device, as described above, the step of annealing at high temperature in a noble gas atmosphere may be added in the process after the growth of a buried oxide film until the growth of a gate polysilicon in order to round STI corners at the boundary between isolation and active regions. Moreover, the step of annealing in a noble gas atmosphere does not involve the effect of nitrogen on the oxide films and the silicon interface, and therefore provides stable fixed charge and interface level. Thus, this method can produce a highly reliable semiconductor device by rounding the corners, eliminating the effect of nitrogen on the silicon interface, and forming a highly reliable gate oxide film with no local variations in thickness.

The present invention has been specifically described above with reference to the drawings, though the invention is not limited to the above embodiment. As a matter of course, various modifications are permitted within the scope of the invention.

1. A method for producing a semiconductor device, comprising the steps of:
forming a trench for device isolation on a silicon substrate; and
annealing the silicon substrate in an atmosphere containing a noble gas at any step after the growth of a buried oxide film until the growth of a gate polysilicon.

2. The method for producing a semiconductor device according to claim 1, wherein:
the noble gas is at least one selected from a group consisting of argon, neon and helium.

3. The method for producing a semiconductor device according to claim 1, wherein:
the annealing is performed at 1,000° C. to 1,200° C. for ten minutes to five hours.

4. The method for producing a semiconductor device according to claim 1, wherein:
the silicon substrate is annealed without being exposed while the silicon substrate is covered with an insulating film.

5. The method for producing a semiconductor device according to claim 1, wherein:
the annealing is performed immediately before channel injection.

6. The method for producing a semiconductor device according to claim 1, wherein:
the annealing is performed immediately before growth of a gate polysilicon.

7. The method for producing a semiconductor device according to claim 1, wherein:
the annealing is performed immediately before CMP.

8. The method for producing a semiconductor device according to claim 1, wherein:
the annealing is performed immediately before the removal of a pad oxide film.
